(19) United States
(12) Patent Application Publication
(10) Pub. No.: US 2026/0084426 A1
(43) Pub. Date: Mar. 26, 2026

(54) LIQUID EJECTING HEAD AND LIQUID EJECTING APPARATUS

(71) Applicant: SEIKO EPSON CORPORATION, Tokyo (JP)

(72) Inventors: Harunobu KOIKE, MATSUMOTO-SHI (JP); Motoki TAKABE, SHIOJIRI-SHI (JP); Nobuaki ITO, SUWA-SHI (JP)

(21) Appl. No.: 19/335,567

(22) Filed: Sep. 22, 2025

(30) Foreign Application Priority Data
Sep. 24, 2024 (JP) 2024-165058

(51) Int. Cl. B41J 2/14; B41J 2/16; H10N 30/00; H10N 30/05; H10N 30/076; H10N 30/50; H10N 30/87; H10N 30/88

(52) U.S. Cl. CPC B41J 2/14233; B41J 2/161; B41J 2/164; H10N 30/05; H10N 30/076; H10N 30/501; H10N 30/708; H10N 30/871; H10N 30/872; H10N 30/883; B41J 2002/14258; B41J 2002/14491

(57) ABSTRACT

A liquid ejecting head includes, stacked in this order from a lower side to an upper side along a stacking direction intersecting an arrangement direction and an extending direction intersecting the arrangement direction: a pressure chamber substrate, a diaphragm, a first common electrode, a first thin film piezoelectric body, a first individual electrode, an insulating layer, a second individual electrode, a second thin film piezoelectric layer, and a second common electrode. The first and second individual electrodes are blocked by the insulating layer in a region where the first and second individual electrodes overlap the pressure chamber when viewed in the stacking direction.

The present application is based on, and claims priority from JP Application Serial Number 2024-165058, filed Sep. 24, 2024, the disclosure of which is hereby incorporated by reference herein in its entirety.

### BACKGROUND

### 1. Technical Field

The present disclosure relates to a liquid ejecting head and a liquid ejecting apparatus.

### 2. Related Art

A liquid ejecting apparatus including a liquid ejecting head for ejecting a liquid such as ink to a medium such as printing paper is proposed in the related art. A piezo-type ink jet printer is known as the liquid ejecting apparatus. In the piezo-type, a piezoelectric element that vibrates a diaphragm that constitutes a part of a wall surface of a pressure chamber is used. The diaphragm is vibrated by the piezoelectric element, and thus the liquid filled in the pressure chamber is ejected from a nozzle.

In a piezoelectric element provided in a liquid ejecting head disclosed in JP-A-2013-256137, a first common electrode, a lower piezoelectric layer of a thin film, an individual electrode, an upper piezoelectric layer of a thin film, and a second common electrode are stacked in order. That is, the piezoelectric element has a configuration in which two thin film piezoelectric bodies are stacked.

However, ejection characteristics of the above-described liquid ejecting head may deteriorate.

### SUMMARY

According to a preferred aspect of the present disclosure, there is provided a liquid ejecting head, including, stacked in this order from a lower side to an upper side along a stacking direction intersecting an arrangement direction and an extending direction intersecting the arrangement direction, a pressure chamber substrate in which a plurality of pressure chambers are provided to be arranged in the arrangement direction, a diaphragm, a first common electrode which is commonly provided for the plurality of pressure chambers and to which a reference voltage that does not change over time is applied, a first thin film piezoelectric body, a first individual electrode which is individually provided for the plurality of pressure chambers so as to extend in the extending direction and to which a driving voltage that changes over time is applied, an insulating layer, a second individual electrode which is individually provided for the plurality of pressure chambers so as to extend in the extending direction and to which the driving voltage that changes over time is applied, a second thin film piezoelectric body, and a second common electrode which is commonly provided for the plurality of pressure chambers and to which the reference voltage is applied, in which the first individual electrode and the second individual electrode are blocked by the insulating layer in a first region where the first individual electrode and the second individual electrode overlap the pressure chamber when viewed in the stacking direction.

In addition, a liquid ejecting apparatus according to a preferred aspect of the present disclosure includes the liquid ejecting head and a control unit that controls an ejection operation of the liquid ejecting head.

### BRIEF DESCRIPTION OF THE DRAWINGS

FIG. 1 is a configuration diagram schematically illustrating a liquid ejecting apparatus according to a first embodiment.

FIG. 2 is an exploded perspective view of the liquid ejecting head illustrated in FIG. 1.

FIG. 3 is a sectional view of a part of the liquid ejecting head illustrated in FIG. 2 and is a sectional view taken along the line III-III in FIG. 2.

FIG. 4 is a sectional view of a part of the liquid ejecting head illustrated in FIG. 2.

FIG. 5 is an enlarged sectional view of a region of the liquid ejecting head illustrated in FIG. 3.

FIG. 6 is a diagram illustrating a planar disposition of an individual electrode and a common electrode.

FIG. 7 is a diagram for describing a driving voltage and a reference voltage.

FIG. 8 is a diagram illustrating an example of an applied voltage applied to two thin film piezoelectric bodies.

FIG. 9 is a diagram illustrating a flow illustrating a manufacturing method of a piezoelectric element, which is a part of a manufacturing method of a liquid ejecting head.

FIG. 10 is a sectional view of a part of a liquid ejecting head according to a second embodiment.

FIG. 11 is a diagram illustrating a flow illustrating a method of manufacturing a piezoelectric element.

FIG. 12 is a sectional view of a part of a liquid ejecting head according to a first modification example.

FIG. 13 is an equivalent circuit diagram illustrating a configuration of a piezoelectric element.

FIG. 14 is a sectional view of a part of a liquid ejecting head according to a fifth modification example.

### DESCRIPTION OF EMBODIMENTS

Hereinafter, preferred embodiments according to the present disclosure will be described with reference to the accompanying drawings. In the drawings, dimensions or scales of each unit are different from the actual dimensions or scales as appropriate, and some units are schematically illustrated for easy understanding. In addition, the scope of the present disclosure is not limited to these forms unless it is stated in the following description that the present disclosure is particularly limited. The term “equal” includes not only a case of being strictly equal but also a case of having a difference in a measurement error range. In addition, the phrase “the element α and the element β are stacked” means that the element α and the element β need only be arranged in an up-down direction, and whether the element α and the element β are in direct contact with each other is not a problem.

The following description will be made by using, as appropriate, an X axis, a Y axis, and a Z axis that intersect each other. One direction along the X axis is referred to as an X1 direction, and a direction opposite to the X1 direction is referred to as an X2 direction. Directions opposite to each other along the Y axis are referred to as a Y1 direction and a Y2 direction. Directions opposite to each other along the Z axis are referred to as a Z1 direction and a Z2 direction. Viewing in the direction along the Z axis is referred to as a “plan view”. The Z axis is typically a vertical axis. The Z1 direction is an upper side, and the Z2 direction is a lower side. However, the Z axis need not be the vertical axis. The X axis, the Y axis, and the Z axis are typically orthogonal to each other, but are not limited to this, and need only intersect each other at, for example, an angle within a range of, for example, 80° or more and 100° or less.

### 1. First Embodiment

### 1-1. Overall Configuration of Liquid Ejecting Apparatus 100

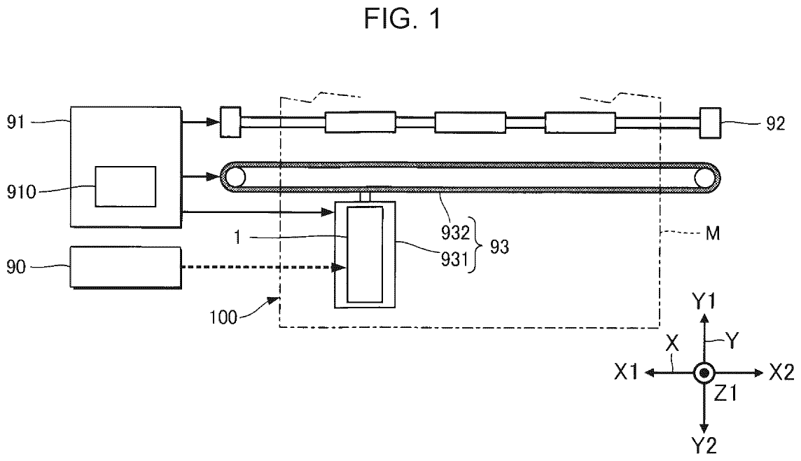

FIG. 1 is a configuration diagram schematically illustrating a liquid ejecting apparatus 100 according to a first embodiment. The liquid ejecting apparatus 100 is an ink jet printing apparatus that ejects ink, which is an example of liquid, to a medium M as liquid droplets. The medium M is typically printing paper. The medium M is not limited to the printing paper, and may be, for example, a printing target made of any material such as a resin film or cloth.

As illustrated in FIG. 1, the liquid ejecting apparatus 100 is equipped with a liquid container 90 for storing the ink. Specific aspects of the liquid container 90 include, for example, a cartridge detachable from the liquid ejecting apparatus 100, a bag-shaped ink pack formed of a flexible film, and an ink tank refillable with ink. A type of the ink stored in the liquid container 90 is optional.

The liquid ejecting apparatus 100 includes a control unit 91, a transport mechanism 92, a moving mechanism 93, and a liquid ejecting head 1. The control unit 91 includes, for example, a processing circuit such as a central processing unit (CPU) or a field programmable gate array (FPGA), and a storage circuit such as a semiconductor memory, and controls an ejection operation from the liquid ejecting head 1. The control unit 91 includes a voltage application circuit 910 that ejects ink from a nozzle N by controlling driving of a piezoelectric element 7 which will be described later. The voltage application circuit 910 applies a reference voltage VBS and a driving voltage Com, which will be described later, to the piezoelectric element 7. In the present embodiment, unless otherwise specified, when a voltage difference is defined, a difference between a voltage of a piezoelectric body lower portion and a voltage of a piezoelectric body upper portion is referred to as a “voltage difference”. The control unit 91 is an example of a “control unit”.

The transport mechanism 92 transports the medium M in the Y2 direction under the control performed by the control unit 91. The moving mechanism 93 reciprocates the liquid ejecting head 1 in the X1 direction and the X2 direction under the control performed by the control unit 91. In the example illustrated in FIG. 1, the moving mechanism 93 includes a substantially box-shaped transport body 931 called a carriage that accommodates the liquid ejecting head 1, and a transport belt 932 to which the transport body 931 is fixed. The number of liquid ejecting heads 1 mounted on the transport body 931 is not limited to one, and may be a plurality. The liquid container 90 may be mounted on the transport body 931 in addition to the liquid ejecting head 1.

Under the control performed by the control unit 91, the liquid ejecting head 1 ejects the ink supplied from the liquid container 90 to the medium M from each of a plurality of nozzles N toward the Z2 direction. The ejection is performed in parallel with the transport of the medium M via the transport mechanism 92 and the reciprocating movement of the liquid ejecting head 1 via the moving mechanism 93, so that an image is formed by the ink on a surface of the medium M.

Such a liquid ejecting apparatus 100 includes the liquid ejecting head 1, which will be described later, and the control unit 91. The control unit 91 includes the voltage application circuit 910 that causes the ejection of the ink from the nozzle N.

### 1-2. Overall Configuration of Liquid Ejecting Head

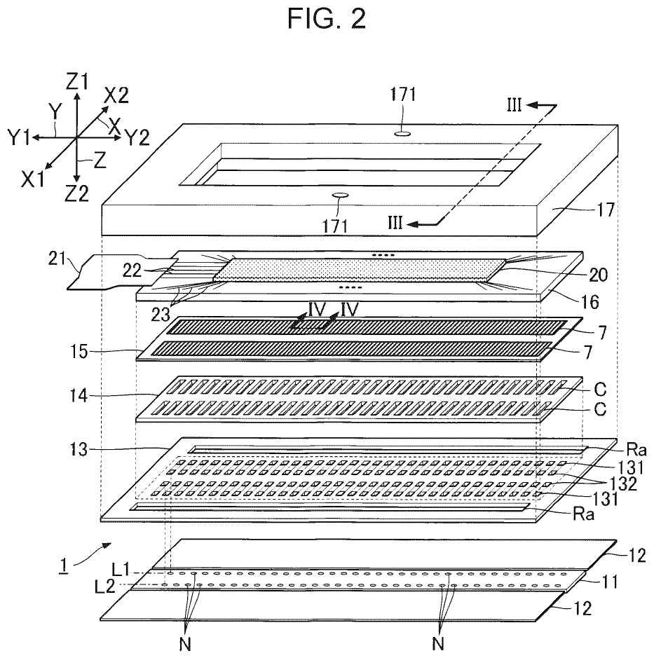

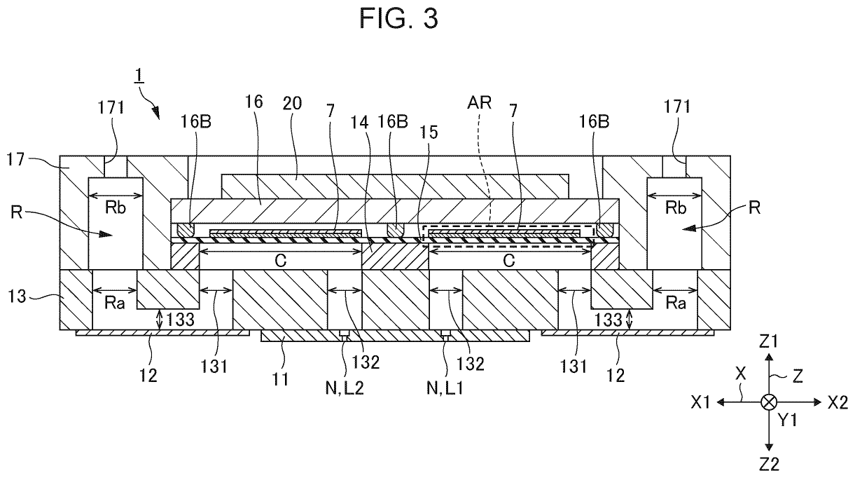

FIG. 2 is an exploded perspective view of the liquid ejecting head 1 illustrated in FIG. 1. FIG. 3 is a sectional view of a part of the liquid ejecting head 1 illustrated in FIG. 2 and is a sectional view taken along the line III-III in FIG. 2. As illustrated in FIG. 2, the liquid ejecting head 1 includes a plurality of nozzles N arranged in a direction along the Y axis. In the example illustrated in FIG. 2, the plurality of nozzles N are divided into a first row L1 and a second row L2 arranged at intervals in a direction along the X axis. Each of the first row L1 and the second row L2 is a set of the plurality of nozzles N linearly arranged in the direction along the Y axis. An element related to each nozzle N in the first row L1 and an element related to each nozzle N in the second row L2 in the liquid ejecting head 1 are substantially symmetrical with each other in the direction along the X axis. In the following description, the element corresponding to the first row L1 will be mainly described, and the description of the element corresponding to the second row L2 will be omitted as appropriate.

The positions of the plurality of nozzles N in the first row L1 and the positions of the plurality of nozzles N in the second row L2 in the direction along the Y axis may be the same as each other or may be different from each other. In addition, the element related to each nozzle N in one of the first row L1 and the second row L2 may be omitted.

As illustrated in FIGS. 2 and 3, the liquid ejecting head 1 includes a nozzle plate 11, a vibration absorber 12, a flow path substrate 13, a pressure chamber substrate 14, a diaphragm 15, a wiring substrate 16, a housing unit 17, and a driving circuit 20. Each of the nozzle plate 11, the vibration absorber 12, the flow path substrate 13, the pressure chamber substrate 14, the diaphragm 15, the wiring substrate 16, and the housing unit 17 is a plate-shaped member that is elongated in the direction along the Y axis. The nozzle plate 11, the flow path substrate 13, the pressure chamber substrate 14, the diaphragm 15, and the wiring substrate 16 are arranged in this order in the Z1 direction.

The nozzle plate 11 is a plate-shaped member in which the plurality of nozzles N are formed. Each of the plurality of nozzles N is a circular through-hole through which the ink passes. The nozzle N ejects the ink by the vibration of the diaphragm 15. The nozzle plate 11 is bonded to the flow path substrate 13 using, for example, an adhesive.

The flow path substrate 13 is formed with a flow path for supplying the ink to the plurality of nozzles N. Specifically, in the flow path substrate 13, a space Ra, a plurality of supply flow paths 131, a plurality of communication flow paths 132, and a supply liquid chamber 133 are formed. The space Ra is an elongated opening extending in the direction along the Y axis in a plan view when viewed in the direction along the Z axis. Each of the supply flow paths 131 and the communication flow paths 132 is a through-hole formed for each nozzle N. The supply liquid chamber 133 is an elongated space extending in the direction along the Y axis over the plurality of nozzles N, and allows the space Ra and the plurality of supply flow paths 131 to communicate with each other. Each of the plurality of communication flow paths 132 overlaps one nozzle N corresponding to the communication flow path 132 in a plan view. The pressure chamber substrate 14 is bonded to the flow path substrate 13 using, for example, an adhesive.

In the pressure chamber substrate 14, a plurality of pressure chambers C are provided. The plurality of pressure chambers C are arranged in the direction along the Y axis. Each pressure chamber C is formed for each nozzle N, and is an elongated space extending in the direction along the X axis in a plan view. The pressure chamber C is a space located between the flow path substrate 13 and the diaphragm 15. The pressure chamber C communicates with the nozzle N via the communication flow path 132 and communicates with the space Ra via the supply flow path 131 and the supply liquid chamber 133. The direction along the Y axis in which the plurality of pressure chambers C are arranged is an example of an “arrangement direction”.

Each of the nozzle plate 11, the flow path substrate 13, and the pressure chamber substrate 14 is manufactured by processing a silicon single crystal substrate by using, for example, dry etching or wet etching. However, other known methods may be used as appropriate for manufacturing each of the nozzle plate 11, the flow path substrate 13, and the pressure chamber substrate 14.

The diaphragm 15 is disposed on a surface of the pressure chamber substrate 14 facing the Z1 direction. The diaphragm 15 is a plate-shaped member that can elastically vibrate.

A plurality of piezoelectric elements 7 corresponding to the nozzles N are disposed on a surface of the diaphragm 15 facing the Z1 direction. Each piezoelectric element 7 has an elongated shape extending in the direction along the X axis in a plan view. The plurality of piezoelectric elements 7 correspond to the plurality of pressure chambers C, and are arranged in the direction along the Y axis. The piezoelectric element 7 is deformed due to the application of a voltage. When the diaphragm 15 vibrates in conjunction with the deformation, the pressure in the pressure chamber C fluctuates, so that the ink is ejected from the nozzle N.

The housing unit 17 is a case for storing the ink supplied to the plurality of pressure chambers C. As illustrated in FIG. 3, a space Rb is formed in the housing unit 17.

The space Rb of the housing unit 17 and the space Ra of the flow path substrate 13 communicate with each other. A space formed by the space Ra and the space Rb functions as a liquid storage chamber R that is a reservoir that stores the ink supplied to the plurality of pressure chambers C. The ink is supplied to the liquid storage chamber R through an inlet 171 formed in the housing unit 17. The ink in the liquid storage chamber R is supplied to the pressure chamber C through the supply liquid chamber 133 and each supply flow path 131.

The vibration absorber 12 is a flexible film that forms a wall surface of the liquid storage chamber R. The vibration absorber 12 is a compliance substrate that absorbs the fluctuation in the pressure of the ink in the liquid storage chamber R.

As illustrated in FIG. 2, an end portion of an external wiring 21 is bonded to a surface of the wiring substrate 16 facing the Z1 direction. The external wiring 21 includes, for example, coupling components such as a flexible printed circuit (FPC) or a flexible flat cable (FFC). The wiring substrate 16 is formed with a plurality of wirings 22 that electrically couple the external wiring 21 and the driving circuit 20, and a plurality of wirings 23 to which the driving voltage Com and the reference voltage VBS output from the driving circuit 20 are supplied.

The wiring substrate 16 is not limited to a rigid substrate, and may be, for example, a flexible printed circuit (FPC) or a flexible flat cable (FFC). In this case, the wiring substrate 16 may also serve as the external wiring 21.

### 1-3. Diaphragm 15

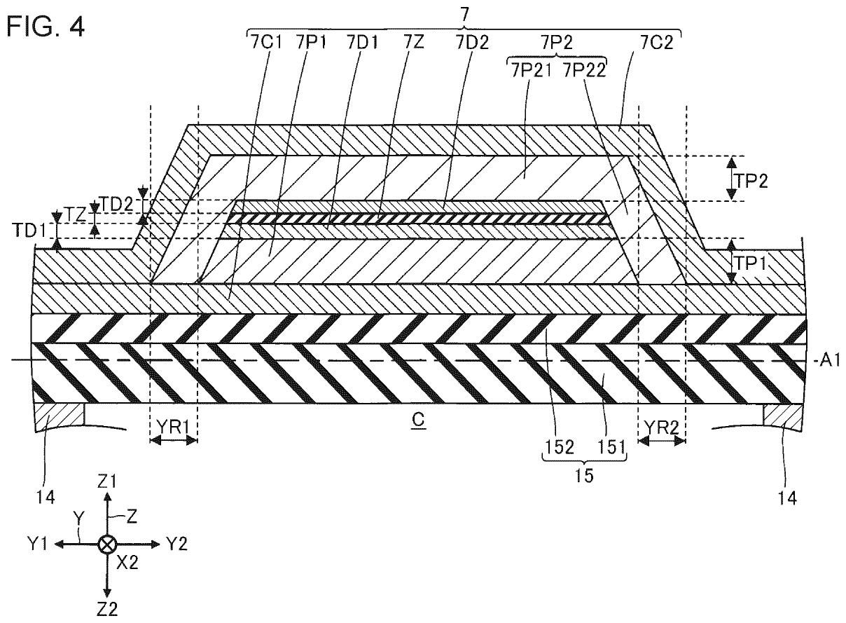

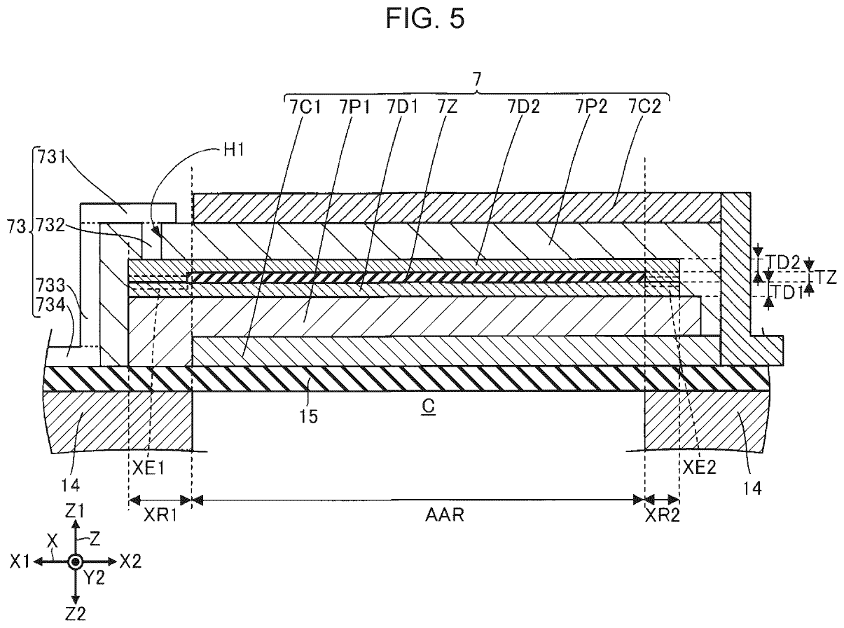

FIG. 4 is a sectional view of a part of the liquid ejecting head 1 illustrated in FIG. 2. The sectional view illustrated in FIG. 2 is a cross section taken along the line IV-IV in FIG. 2. FIG. 5 is an enlarged sectional view of a region AR of the liquid ejecting head 1 illustrated in FIG. 3. The diaphragm 15 illustrated in FIGS. 4 and 5 vibrates in response to the vibration of the piezoelectric element 7. The diaphragm 15 includes, for example, a first layer 151 and a second layer 152. The first layer 151 and the second layer 152 are stacked in this order from the lower side to the upper side, that is, in the Z1 direction.

For example, the first layer 151 is an elastic film formed of silicon oxide (SiO₂). The elastic film is formed, for example, by thermally oxidizing one surface of a silicon single crystal substrate. The second layer 152 is an insulating film formed of zirconium oxide (ZrO₂), for example. The insulating film is formed, for example, by forming a zirconium layer by a sputtering method and thermally oxidizing the layer. Zirconium oxide has excellent electric insulation, mechanical strength, and toughness. Therefore, the diaphragm 15 includes the second layer 152 containing zirconium oxide, so that the characteristics of the diaphragm 15 can be enhanced.

Another layer such as a metal oxide or the like may be interposed between the first layer 151 and the second layer 152. In addition, a part or all of the diaphragm 15 may be integrally formed with the pressure chamber substrate 14. Further, the diaphragm 15 may be formed of a layer of a single material. FIG. 4 illustrates a neutral axis A1 of the diaphragm 15 and the piezoelectric element 7. The neutral axis A1 is at a different position depending on materials, thicknesses, and the like of the diaphragm 15 and the piezoelectric element 7, but is set to be present in the diaphragm 15 in the present embodiment. Since the piezoelectric element 7 is more easily displaced as it is separated from the neutral axis A1, when the neutral axis A1 is disposed on the lower side of the piezoelectric element 7, that is, in the diaphragm 15, the entire piezoelectric element 7 can be separated to some extent from the neutral axis A1, and displacement efficiency can be increased.

### 1-4. Characteristics of Piezoelectric Element 7

In order to increase the amount of displacement per unit voltage, an aspect is conceivable in which a piezoelectric element is formed by sequentially stacking a first common electrode, a first thin film piezoelectric body, an individual electrode, a second thin film piezoelectric body, and a second common electrode. Hereinafter, this aspect may be referred to as a “comparative aspect”. However, the ejection characteristics of the liquid ejecting head in the comparative embodiment may deteriorate. The ejection characteristics are, for example, one or both of an ejection amount and an ejection speed. In a liquid ejecting head according to the comparative aspect, a direction of an electric field generated by the first common electrode and the individual electrode and a direction of an electric field generated by the individual electrode and the second common electrode are opposite to each other. Therefore, in the first thin film piezoelectric body, a part of the electric field generated by the first common electrode and the individual electrode is canceled by the electric field generated by the individual electrode and the second common electrode, and the amount of deformation of the first thin film piezoelectric body is reduced. Similarly, in the second thin film piezoelectric body, a part of the electric field generated by the individual electrode and the second common electrode is canceled by the electric field generated by the first common electrode and the individual electrode, and the amount of deformation of the second thin film piezoelectric body is reduced. That is, in the liquid ejecting head according to the comparative embodiment, a part of one electric field of the two electric fields is canceled by the other electric field, and the amount of deformation of the two thin film piezoelectric bodies is reduced, and accordingly, the ejection characteristics are reduced.

Therefore, in the piezoelectric element 7 according to the first embodiment, the individual electrode is divided into upper and lower parts, and the insulating layer 7Z is provided between the divided parts, so that a part of the one electric field of the two electric fields is suppressed from being canceled by the other electric field.

### 1-5. Piezoelectric Element 7

As illustrated in FIG. 3, the piezoelectric element 7 overlaps the pressure chamber C described above in a plan view. As illustrated in FIGS. 4 and 5, the piezoelectric element 7 is disposed on the diaphragm 15. The piezoelectric element 7 includes a first common electrode 7C1, a first thin film piezoelectric body 7P1, a first individual electrode 7D1, an insulating layer 7Z, a second individual electrode 7D2, and a second common electrode 7C2. The first common electrode 7C1, the first thin film piezoelectric body 7P1, the first individual electrode 7D1, the insulating layer 7Z, the second individual electrode 7D2, and the second common electrode 7C2 are stacked in this order from the lower side to the upper side. The first common electrode 7C1 and the second common electrode 7C2 are substantially common to the plurality of piezoelectric elements 7. Another layer such as a layer for enhancing adhesion may be appropriately interposed between layers of the piezoelectric element 7 or between the piezoelectric element 7 and the diaphragm 15. The direction along the Z axis, which is a direction in which each element of the piezoelectric element 7 is stacked, is an example of a “stacking direction”.

In the following, the first common electrode 7C1 and the second common electrode 7C2 may be referred to as a common electrode 7C without distinction. In addition, the first thin film piezoelectric body 7P1 and the second thin film piezoelectric body 7P2 may be referred to as a thin film piezoelectric body 7P without distinction. Further, the first individual electrode 7D1 and the second individual electrode 7D2 may be referred to as an individual electrode 7D.

The thin film piezoelectric body 7P is separated between the plurality of piezoelectric elements 7 by a through-hole HO, which will be described later, in a range overlapping the pressure chamber C in a plan view when viewed in the direction along the Z axis, but the thin film piezoelectric body 7P is connected in a range not overlapping the pressure chamber C and is a continuous member. However, the thin film piezoelectric body 7P may not be a continuous member.

### 1-5a. Common Electrode 7C

The common electrode 7C is commonly provided for the plurality of pressure chambers C described above. The common electrode 7C has a strip shape extending in the direction along the Y axis so as to be continuous with the plurality of pressure chambers C. The reference voltage VBS that does not change over time is applied to the common electrode 7C. As illustrated in FIG. 4, in the direction along the Y axis, in a portion where the thin film piezoelectric body 7P does not exist, the first common electrode 7C1 and the second common electrode 7C2 are in contact with each other. Therefore, a common voltage is applied to the first common electrode 7C1 and the second common electrode 7C2.

Examples of the material of the common electrode 7C include a metal material such as platinum (Pt), iridium (Ir), aluminum (Al), nickel (Ni), gold (Au), or copper (Cu), or an alloy. The common electrode 7C may be a single layer or a plurality of layers. The common electrode 7C has, for example, a stacked structure in which a layer formed of platinum is stacked on a layer formed of iridium.

### 1-5b. Individual Electrode 7D

The individual electrode 7D is individually provided for each of the plurality of pressure chambers C. The driving voltage Com that changes over time is applied to the individual electrode 7D. In the present embodiment, the same driving voltage Com is applied to each of the two individual electrodes 7D.

Examples of the material of the individual electrode 7D include a metal material such as platinum, iridium, aluminum, nickel, gold, or copper, or an alloy. The individual electrode 7D may be a single layer or a plurality of layers.

### 1-5c. Thin Film Piezoelectric Body 7P

The thin film piezoelectric body 7P is made of a composite oxide. Specifically, the thin film piezoelectric body 7P is made of a piezoelectric material having a perovskite crystal structure. Examples of the piezoelectric material include lead titanate (PbTiO₃), lead zirconate titanate (PZT:Pb(Zr, Ti)O₃), lead zirconite (PbZrO₃), lead lanthanum titanate ((Pb, La), TiO₃), lead lanthanum titanate zirconate ((Pb, La) (Zr, Ti)O₃), lead zirconite niobate titanate (Pb(Zr, Ti, Nb)O₃), and lead magnesium niobate zirconite titanate (Pb(Zr, Ti)(Mg, Nb)O₃). Among these, lead zirconate titanate (PZT) is suitably used as a constituent material of the thin film piezoelectric body. In addition, the thin film piezoelectric body may contain a small amount of other elements such as impurities. Each of the two thin film piezoelectric bodies 7P may be a single layer or a plurality of layers.

In addition, from another viewpoint, it is preferable that all of the two thin film piezoelectric bodies 7P are made of the same material. Since each of the two thin film piezoelectric bodies 7P is made of the same material, the manufacturing is easy, and desired physical properties can be easily designed by controlling, for example, a film thickness. However, the two thin film piezoelectric bodies 7P may be formed of different materials.

In addition, each of the two thin film piezoelectric bodies 7P is a thin film. Specifically, a thickness of each of the two thin film piezoelectric bodies 7P is preferably 5 μm or less, and more preferably 2 μm or less. The thicknesses of the two thin film piezoelectric bodies 7P may be the same or different.

As understood from FIGS. 4 and 5, each of the two thin film piezoelectric bodies 7P is formed to cover a part of at least one electrode of the first common electrode 7C1 and the two individual electrodes 7D. Specifically, as illustrated in FIG. 5, the first thin film piezoelectric body 7P1 is formed to cover the first common electrode 7C1 at an end portion in the X1 direction. As illustrated in FIG. 4, the second thin film piezoelectric body 7P2 includes a parallel portion 7P21 which is a portion parallel to the XY plane, and an inclined portion 7P22 which is inclined with respect to the XY plane and the direction along the Z axis. Although reference numerals are not given in FIG. 4 in order to avoid complication of the drawing, the inclined portion 7P22 is present at both ends in the Y1 direction and the Y2 direction with respect to the parallel portion 7P21. An end of the inclined portion 7P22 in the Z2 direction is in contact with the first common electrode 7C1. In FIG. 4, the second thin film piezoelectric body 7P2 is formed to cover the first thin film piezoelectric body 7P1, the first individual electrode 7D1, the insulating layer 7Z, and the second individual electrode 7D2 at end portions in the Y1 direction and the Y2 direction. Therefore, the thickness of each of the two thin film piezoelectric bodies 7P is different between a portion overlapping the electrode or the like and a portion not overlapping the electrode or the like in a plan view. Therefore, a thinnest thickness TP1 of the first thin film piezoelectric body 7P1 and a thinnest thickness TP2 of the second thin film piezoelectric body 7P2 illustrated in FIG. 4 are preferably 5 μm or less, and more preferably 2 μm or less.

In the following description, as understood from FIG. 5, in a plan view, a region of the first individual electrode 7D1 and the second individual electrode 7D2 overlapping the pressure chamber C may be referred to as an active region AAR. On the other hand, in a plan view, of the two regions in which the first individual electrode 7D1 and the second individual electrode 7D2 do not overlap the pressure chamber C, a region positioned in the X1 direction of the active region AAR may be referred to as an inactive region XR1, and a region positioned in the X2 direction of the active region AAR may be referred to as an inactive region XR2. In addition, as illustrated in FIG. 4, in the direction along the Y axis, of the two regions in the piezoelectric element 7 in which the first individual electrode 7D1 and the second individual electrode 7D2 are not provided, a region positioned in the Y1 direction may be described as an inactive region YR1, and a region positioned in the Y2 direction may be described as an inactive region YR2. The active region AAR is an example of a “first region”, the inactive region XR1 and the inactive region XR2 are examples of a “second region”, and the inactive region YR1 and the inactive region YR2 are examples of a “third region”.

As illustrated in FIG. 5, in a coupling region XE1 included in the inactive region XR1, the first individual electrode 7D1 and the second individual electrode 7D2 are coupled to each other. Therefore, the first individual electrode 7D1 and the second individual electrode 7D2 have the same potential. Further, in a coupling region XE2 included in the inactive region XR2, the first individual electrode 7D1 and the second individual electrode 7D2 are coupled to each other.

In addition, as understood from FIG. 5, the coupling region XE1 and a second wiring portion 732 overlap each other in a plan view. Further, as understood from FIG. 5, a length of the coupling region XE1 in the direction along the X axis is longer than a length of the coupling region XE2 in the direction along the X axis. The smaller the length of the inactive region XR1 and the inactive region XR2 in the direction along the X axis, the smaller the size of the liquid ejecting head 1 in the direction along the X axis. However, in order to provide a place where the second wiring portion 732 and the second individual electrode 7D2 are coupled, the inactive region XR1 needs to secure a certain length. Therefore, in the first embodiment, the liquid ejecting head 1 can be miniaturized in the direction along the X axis by securing the place where the second wiring portion 732 and the second individual electrode 7D2 are coupled, as compared with the aspect in which the length of the coupling region XE1 in the direction along the X axis is shorter than the length of the coupling region XE2 in the direction along the X axis. However, the length of the coupling region XE1 in the direction along the X axis may be shorter than the length of the coupling region XE2 in the direction along the X axis.

As illustrated in FIG. 4, in the inactive region YR1 and the inactive region YR2, the first common electrode 7C1, the second thin film piezoelectric body 7P2, and the second common electrode 7C2 are stacked in this order from the lower side to the upper side, and the first thin film piezoelectric body 7P1 and the insulating layer 7Z are not stacked.

As understood from FIG. 5, the position of the end of the first common electrode 7C1 and the second common electrode 7C2 in the X1 direction on the X axis substantially match the position of the pressure chamber C in the X1 direction on the X axis.

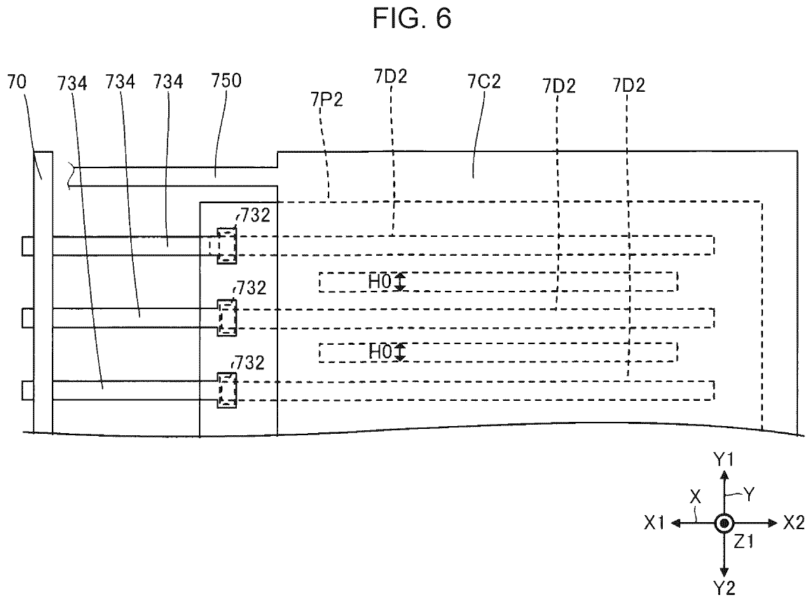

FIG. 6 is a diagram illustrating a planar disposition of the individual electrode 7D and the common electrode 7C. As illustrated in FIG. 6, each individual electrode 7D has an elongated shape extending along the X axis. The plurality of individual electrodes 7D are separated from each other and arranged along the Y axis. As illustrated in FIG. 5, one end of each individual electrode 7D in the longitudinal direction along the X axis is coupled to an individual wiring portion 73 for applying the driving voltage Com. A direction along the X axis in which each individual electrode 7D extends is an example of an “extending direction”.

The individual wiring portion 73 includes a first wiring portion 731, the second wiring portion 732, a third wiring portion 733, and a fourth wiring portion 734. The first wiring portion 731 extends in the direction along the X axis and is provided on the upper side of the second thin film piezoelectric body 7P2. The second wiring portion 732 branches from an end portion of the first wiring portion 731 in the X2 direction, extends in the direction along the Z axis to penetrate the second thin film piezoelectric body 7P2, and is coupled to the second individual electrode 7D2. Specifically, the second wiring portion 732 penetrates a contact hole H1 penetrating the second thin film piezoelectric body 7P2. The third wiring portion 733 extends in the direction along the Z axis along side surfaces of the second thin film piezoelectric body 7P2 and the first thin film piezoelectric body 7P1 in the X1 direction, is coupled to the first wiring portion 731 at the end portion in the Z1 direction, and is coupled to the fourth wiring portion 734 at the end portion in the Z2 direction. The fourth wiring portion 734 is provided on a surface of the diaphragm 15 facing the Z1 direction, and is coupled to a wiring 70 extending along the Y axis. The wiring 70 is electrically coupled to the driving circuit 20 mounted on the wiring substrate 16 via a plurality of conductive bumps 16B described above. As described above, in the coupling region XE2, the first individual electrode 7D1 and the second individual electrode 7D2 are coupled to each other. Therefore, the two individual electrodes 7D are electrically coupled to the driving circuit 20 via the individual wiring portion 73 and the wiring 70.

A lead wiring 750 is coupled to a corner portion of the second common electrode 7C2. The lead wiring 750 is electrically coupled to the driving circuit 20 mounted on the wiring substrate 16 via the plurality of conductive bumps 16B described above. As described above, since there is a place where the first common electrode 7C1 and the second common electrode 7C2 are in contact with each other, the first common electrode 7C1 and the second common electrode 7C2 are electrically coupled to the driving circuit 20 via the lead wiring 750.

### 1-5d. Insulating Layer 7Z

As illustrated in FIG. 5, in the active region AAR, the first individual electrode 7D1 and the second individual electrode 7D2 are blocked by the insulating layer 7Z. It is preferable that the insulating layer 7Z is not present in the inactive region XR1 and the inactive region XR2, but the insulating layer 7Z may be present. In the example of FIG. 5, the insulating layer 7Z is present at an end portion of the inactive region XR1 in the X2 direction, and the insulating layer is not present in the inactive region XR2. The insulating layer 7Z may be made of any material as long as it is made of an insulator, and is formed of, for example, a zirconium oxide such as zirconium dioxide (ZrO₂). The fact that the insulating layer 7Z is formed of zirconium oxide is an example that “the insulating layer contains zirconium”. The fact that the insulating layer 7Z contains zirconium means that the insulating layer 7Z contains zirconium atoms.

The insulating layer 7Z is thinner than the first individual electrode 7D1 and the second individual electrode 7D2. As can be understood from FIG. 5, the second individual electrode 7D2 is thickest in the coupling region XE1 and the coupling region XE2, and thinnest in the active region AAR. Therefore, the fact that the insulating layer 7Z is thinner than the first individual electrode 7D1 and the second individual electrode 7D2 means that the insulating layer 7Z is thinner than the portions of the active regions AAR of the first individual electrode 7D1 and the second individual electrode 7D2. Specifically, as illustrated in FIGS. 4 and 5, a thickness TZ of the insulating layer 7Z in the direction along the Z axis is shorter than a thickness TD1 of the first individual electrode 7D1 in the direction along the Z axis and a thickness TD2 of the second individual electrode 7D2 in the direction along the Z axis. In addition, the thickness TD2 is thinner than the thickness TD1. Therefore, the following relationship of Expression (1) is established.

$$TZ < TD 2 < TD 1 \qquad ( 1 )$$

### 1-5e. Orientation Control Layer 7H

Although not illustrated, an orientation control layer 7H is provided between the first thin film piezoelectric body 7P1 and the first common electrode 7C1 and between the second thin film piezoelectric body 7P2 and the second common electrode 7C2 in the active region AAR. The orientation control layer 7H controls orientation of each of the first thin film piezoelectric body 7P1 and the second thin film piezoelectric body 7P2.

By providing the orientation control layer 7H, the orientation control of each of the first thin film piezoelectric body 7P1 and the second thin film piezoelectric body 7P2 can be performed. As a specific orientation control, the orientation control layer 7H can cause the crystals of the first thin film piezoelectric body 7P1 and the second thin film piezoelectric body 7P2 to be preferentially oriented in a predetermined crystal plane orientation or adjust an orientation degree of a predetermined crystal plane orientation. For example, the orientation control layer 7H causes the crystals of the first thin film piezoelectric body 7P1 and the second thin film piezoelectric body 7P2 to be preferentially oriented to the (100) plane, and thus the piezoelectric characteristics of the piezoelectric element 7 can be improved as compared with a case where the crystals are preferentially oriented to the (110) plane. Therefore, the displacement efficiency of the piezoelectric element 7 can be increased.

In addition, for example, the orientation control layer 7H can adjust the orientation degree of the crystals of the first thin film piezoelectric body 7P1 and the second thin film piezoelectric body 7P2 to the (100) plane. Therefore, the orientation control layer 7H that controls the orientation of the first thin film piezoelectric body 7P1 and the second thin film piezoelectric body 7P2 is provided, so that the second thin film piezoelectric body 7P2 can be set to a desired orientation degree. Therefore, optimum physical property values can be set for the first thin film piezoelectric body 7P1 and the The orientation control layer 7H contains, for example, titanium (Ti) or a composite oxide having a perovskite structure. The composite oxide having the perovskite structure contains, for example, any of Ni (nickel), lanthanum (La), Bi (bismuth), lead (Pb), titanium (Ti), and iron (Fe) as constituent elements. In the present embodiment, it is preferable that the orientation control layer 7H contains titanium. The fact that the orientation control layer 7H contains titanium means that the orientation control layer 7H contains titanium atoms.

Specifically, examples of the composite oxide having the perovskite structure include lead titanate (PbTiO₃), lanthanum nickelate (LaNiO₃), PbₓBi₍ₐ₋ₓ₎Fe_{y}Ti_{(b-y)}O_{z}, and PbₓFe_{y}Ti_{(1-y)}O_{z}. The orientation control layer 7H may be a single layer or a plurality of layers. Therefore, the material of the orientation control layer 7H may be one type or a plurality of types.

In the above-described PbₓBi₍ₐ₋ₓ₎Fe_{y}Ti_{(b-y)}O_{z}, a>x and b>y. In addition, it is preferable that x/(a−x) satisfies 0.04<x/(a−x)<1.40. Furthermore, in order to perform the orientation to the (100) plane, it is more preferable that x/(a−x)<0.72. It is preferable that b=1, and it is preferable that a/b satisfies 0.8<(a/b)<1.4. In addition, it is preferable that z satisfies 2.8<z<3.2.

Examples satisfying these preferable ranges include, for example, a=1.2, b=1.0, x=0.1, and y=0.5.

In addition, in PbₓFe_{y}Ti_{(1-y)}O_{z}, x satisfies the relationship of 1.00≤x<2.00. In order to perform the orientation to the (100) plane, it is preferable that x satisfies the relationship of 1.00≤x<1.50. Further, y satisfies the relationship of 0.10≤y≤0.90. In order to perform the orientation to the (100) plane, it is preferable to satisfy the relationship of 0.20≤y≤0.80. Further, z typically satisfies the relationship of z=3.00. However, z may not satisfy the relationship.

Hereinafter, PbₓBi₍ₐ₋ₓ₎Fe_{y}Ti_{(b-y)}O_{z} will be simply referred to as “PbBiFeTiO”. PbₓFe_{y}Ti_{(1-y)}O_{z} will be simply referred to as “PbFeTiO”.

For example, the orientation control layer 7H preferably contains Bi, Fe, Ti, and Pb. In this case, specifically, for example, the orientation control layer 7H is PbBiFeTiO. The PbBiFeTiO is superior in the performance of orientation control of the first thin film piezoelectric body 7P1 and the second thin film piezoelectric body 7P2 as compared with PbFeTiO, lanthanum nickelate, and titanium. Therefore, for example, the orientation degrees of the first thin film piezoelectric body 7P1 and the second thin film piezoelectric body 7P2 to the (100) plane can be increased. Therefore, the piezoelectric efficiency of the first thin film piezoelectric body 7P1 and the second thin film piezoelectric body 7P2 can be increased.

### 1-6. Operation of Piezoelectric Element 7

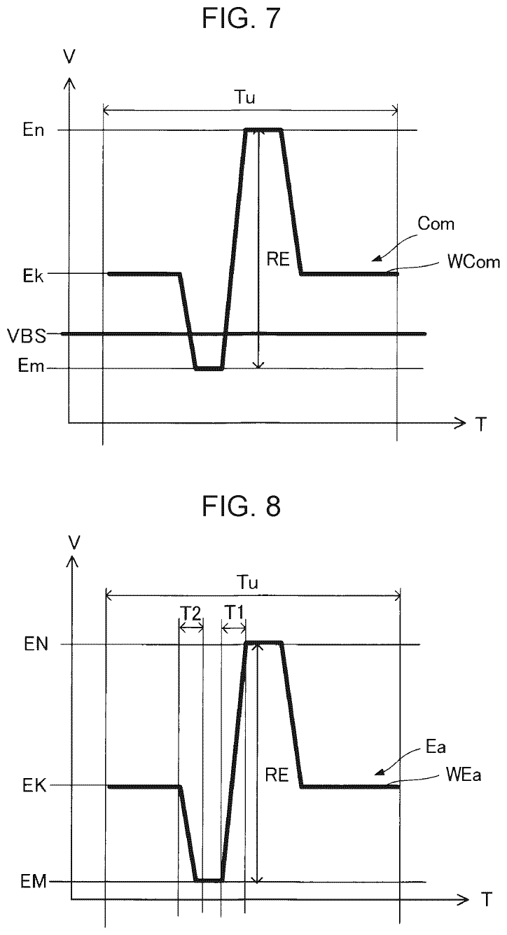

FIG. 7 is a diagram for describing the driving voltage Com and the reference voltage VBS. In FIG. 7, a horizontal axis is a time, and a vertical axis is a voltage [V]. The voltage is applied to the piezoelectric element 7 by the voltage application circuit 910 described above. Specifically, the voltage application circuit 910 applies a voltage to the two thin film piezoelectric bodies 7P via the two common electrodes 7C and the two individual electrodes 7D. The first thin film piezoelectric body 7P1 is deformed according to the voltage applied between the first common electrode 7C1 and the first individual electrode 7D1. The second thin film piezoelectric body 7P2 is deformed according to the voltage applied between the second individual electrode 7D2 and the second common electrode 7C2.

The driving voltage Com corresponding to the ejection amount of the ink is applied to each of the two individual electrodes 7D. The driving voltage Com changes over time. The driving voltage Com includes a driving waveform WCom. The driving waveform WCom is repeated in a unit period Tu. The driving waveform WCom includes an intermediate voltage Ek, a maximum voltage En, and a minimum voltage Em. The maximum voltage En is a maximum value of the driving voltage Com. The minimum voltage Em is a minimum value of the driving voltage Com. The driving waveform WCom decreases from the intermediate voltage Ek to the minimum voltage Em, maintains the minimum voltage Em, increases from the minimum voltage Em to the maximum voltage En, maintains the maximum voltage En, and then decreases to the intermediate voltage Ek. The driving waveform WCom illustrated in FIG. 7 is merely an example, and the driving voltage Com may have another waveform.

A constant reference voltage VBS is applied to each of the two common electrodes 7C regardless of the ejection amount of the ink. The reference voltage VBS does not change regardless of the lapse of time and is constant. In the illustrated example, the reference voltage VBS is a voltage value higher than the minimum voltage Em of the driving voltage Com, but the present disclosure is not limited to this. In addition, the reference voltage VBS may be a GND potential, that is, 0 [V].

FIG. 8 is an example of an applied voltage Ea applied to the two thin film piezoelectric bodies 7P. The applied voltage Ea illustrated in FIG. 8 is a value obtained by subtracting the reference voltage VBS from the driving voltage Com illustrated in FIG. 7 at each time.

By applying the driving voltage Com and the reference voltage VBS, a voltage of a difference between the driving voltage Com and the reference voltage VBS is applied to the first thin film piezoelectric body 7P1 between the first common electrode 7C1 and the first individual electrode 7D1, and the first thin film piezoelectric body 7P1 is deformed. Similarly, by applying the driving voltage Com and the reference voltage VBS, a voltage of a difference between the driving voltage Com and the reference voltage VBS is applied to the second thin film piezoelectric body 7P2 between the second common electrode 7C2 and the second individual electrode 7D2, and the second thin film piezoelectric body 7P2 is deformed.

In FIG. 8, a horizontal axis is a time, and a vertical axis is a voltage [V]. The applied voltage Ea includes a waveform WEa. The waveform WEa includes an intermediate voltage EK, a maximum voltage EN, and a minimum voltage EM. The maximum voltage EN is a difference between the maximum voltage En of the driving voltage Com and the reference voltage VBS. The minimum voltage EM is a difference between the minimum voltage Em of the driving voltage Com and the reference voltage VBS. The waveform WEa illustrated in FIG. 8 is merely an example, and changes depending on the driving voltage Com and the reference voltage VBS.

Since the reference voltage VBS is constant, a voltage range RE of the applied voltage Ea is equal to a voltage range RE of the driving voltage Com.

When the maximum voltage EN illustrated in FIG. 8 is applied to the two thin film piezoelectric bodies 7P, the first thin film piezoelectric body 7P1 is affected by an electric field directed in the Z2 direction. The second thin film piezoelectric body 7P2 is affected by an electric field directed in the Z1 direction. As described above, the directions of the electric fields that affect the two thin film piezoelectric bodies 7P are different, but the magnitudes of the electric fields are the same.

The piezoelectric element 7 including the two thin film piezoelectric bodies 7P described above is deformed such that the piezoelectric element 7 and the diaphragm 15 are bent in the Z1 direction in an expansion period T2 in which the voltage is lowered from the intermediate voltage EK illustrated in FIG. 8 to the minimum voltage EM and the pressure chamber C is expanded. That is, the piezoelectric element 7 is deformed toward the upper side so as to expand the pressure chamber C. As a result, the ink is taken into the pressure chamber C. Next, in a contraction period T1 in which the voltage is increased from the minimum voltage EM to the maximum voltage EN to contract the pressure chamber C, the piezoelectric element 7 and the diaphragm 15 are deformed to be bent in the Z2 direction. That is, the piezoelectric element 7 is deformed toward the lower side so as to contract the pressure chamber C. As a result, the ink in the pressure chamber C is ejected from the nozzle N.

### 1-7. Manufacturing Method of Piezoelectric Element 7

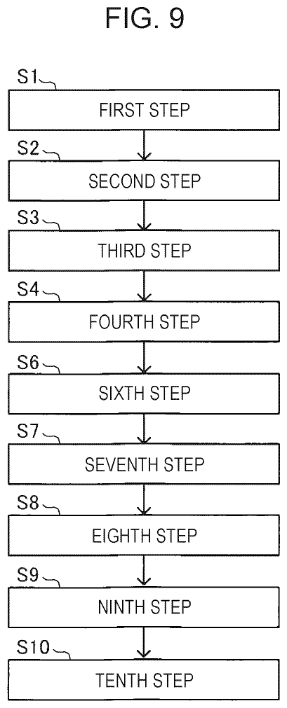

FIG. 9 is a flow illustrating a manufacturing method of the piezoelectric element 7, which is a part of the manufacturing method of the liquid ejecting head 1. As illustrated in FIG. 9, the manufacturing method of the piezoelectric element 7 includes a first step S1, a second step S2, a third step S3, a fourth step S4, a sixth step S6, a seventh step S7, an eighth step S8, a ninth step S9, and a tenth step S10. These steps are performed in this order.

In the first step S1, the first common electrode 7C1 is formed on the diaphragm 15. The first common electrode 7C1 is formed by, for example, a known film forming technique such as a vapor deposition method or a sputtering method.

In the second step S2, the orientation control layer 7H is formed on the first common electrode 7C1, and the first thin film piezoelectric body 7P1 is further formed. The first thin film piezoelectric body 7P1 is formed by, for example, forming a precursor layer of the first thin film piezoelectric body 7P1 by a sol-gel method and crystallizing the precursor layer by firing. In addition, the first thin film piezoelectric body 7P1 may be formed by using a sputtering method. However, when the sol-gel method is used, the first thin film piezoelectric body 7P1 having a thickness of 2 μm or less, and more preferably 1 μm or less can be suitably formed.

In the third step S3, the first individual electrode 7D1 is formed on the first thin film piezoelectric body 7P1. The first individual electrode 7D1 is formed by, for example, a known film forming technique such as a vapor deposition method or a sputtering method.

In the fourth step S4, the insulating layer 7Z is formed on the first individual electrode 7D1. The insulating layer 7Z is formed by, for example, a known film forming technique such as a vapor deposition method or a sputtering method.

In the sixth step S6, the second individual electrode 7D2 is formed on the insulating layer 7Z. The second individual electrode 7D2 is formed by, for example, a known film forming technique such as a vapor deposition method or a sputtering method.

In the seventh step S7, the first thin film piezoelectric body 7P1, the first individual electrode 7D1, the insulating layer 7Z, and the second individual electrode 7D2 are patterned. The patterning is performed by a known processing technique using etching or the like.

In the eighth step S8, the orientation control layer 7H is formed so as to cover the first thin film piezoelectric body 7P1, the first individual electrode 7D1, the insulating layer 7Z, and the second individual electrode 7D2, and the second thin film piezoelectric body 7P2 is further formed. The second thin film piezoelectric body 7P2 is formed by, for example, a known film forming technique such as a vapor deposition method or a sputtering method.

In the ninth step S9, the second thin film piezoelectric body 7P2 is patterned.

In the tenth step S10, the second common electrode 7C2 is formed on the second thin film piezoelectric body 7P2. The second common electrode 7C2 is formed by a known film forming technique such as a vapor deposition method or a sputtering method, and a known processing technique using photolithography, etching, or the like.

After the end of the tenth step S10, the piezoelectric element 7 is manufactured by firing the piezoelectric element 7 at a high temperature.

### 1-8. Summary of First Embodiment

In the liquid ejecting head 1, the pressure chamber substrate 14 in which the plurality of pressure chambers C are provided to be arranged in the direction along the Y axis, the diaphragm 15, the first common electrode 7C1 which is commonly provided for the plurality of pressure chambers C and to which the reference voltage VBS that does not change over time is applied, the first thin film piezoelectric body 7P1, the first individual electrode 7D1 which is individually provided for the plurality of pressure chambers so as to extend in the direction along the X axis and to which the driving voltage Com that changes over time is applied, the insulating layer 7Z, the second individual electrode 7D2 which is individually provided for the plurality of pressure chambers so as to extend in the direction along the X axis and to which the driving voltage Com that changes over time is applied, the second thin film piezoelectric body 7P2, and the second common electrode 7C2 which is commonly provided for the plurality of pressure chambers C and to which the reference voltage VBS is applied, are stacked in this order from a lower side to an upper side along the direction along the Z axis, and the first individual electrode 7D1 and the second individual electrode 7D2 are blocked by the insulating layer 7Z in the active region AAR where the first individual electrode 7D1 and the second individual electrode 7D2 overlap the pressure chamber C when viewed in the direction along the Z axis.

According to the first embodiment, the electric field generated by the first individual electrode 7D1 and the first common electrode 7C1 and the electric field generated by the second individual electrode 7D2 and the second common electrode 7C2 are canceled out by each other, and the cancellation is suppressed by the insulating layer 7Z. Therefore, the deterioration of the ejection characteristics of the liquid ejecting head 1 can be suppressed.

Further, the first individual electrode 7D1 and the second individual electrode 7D2 are coupled to each other in the inactive region XR1 in which the first individual electrode 7D1 and the second individual electrode 7D2 do not overlap the pressure chamber C when viewed in the direction along the Z axis.

According to the first embodiment, it is not necessary to prepare a wiring coupled to each of the first individual electrode 7D1 and the second individual electrode 7D2 as compared with an aspect in which the first individual electrode 7D1 and the second individual electrode 7D2 are not coupled.

In addition, the first individual electrode 7D1 and the second individual electrode 7D2 are coupled to each other in both of one end and another end of the first individual electrode 7D1 and the second individual electrode 7D2 in the direction along the X axis in the inactive region XR1 and the inactive region XR2.

In an aspect in which one of one end and another end of the first individual electrode 7D1 and the second individual electrode 7D2 in the direction along the X axis is coupled, a voltage drop occurs at an uncoupled end among both ends of one end and another end. When the voltage drop occurs, the voltage applied to the thin film piezoelectric body 7P decreases, so that the ejection characteristics deteriorate. Therefore, in the first embodiment, the occurrence of the voltage drop can be suppressed by suppressing the deterioration of the ejection characteristics as compared with the aspect in which one of one end and another end of the first individual electrode 7D1 and the second individual electrode 7D2 in the direction along the X axis is coupled.

In addition, the inactive region YR1 and the inactive region YR2 in which the first individual electrode 7D1 and the second individual electrode 7D2 are not provided in the direction along the Y axis, the first common electrode 7C1, the second thin film piezoelectric body 7P2, and the second common electrode 7C2 are stacked in this order from the lower side to the upper side, and the first thin film piezoelectric body 7P1 and the insulating layer 7Z are not stacked.

In addition, the insulating layer 7Z is thinner than the first individual electrode 7D1 and the second individual electrode 7D2.

The insulating layer 7Z may be able to suppress the electric field generated by the first individual electrode 7D1 and the first common electrode 7C1 and the electric field generated by the second individual electrode 7D2 and the second common electrode 7C2 from canceling each other. According to the first embodiment, the deformation of the piezoelectric element 7 can be suppressed from being hindered by the insulating layer 7Z as compared with the aspect in which the insulating layer 7Z is thicker than the first individual electrode 7D1 and the second individual electrode 7D2.

In addition, the second individual electrode 7D2 is thinner than the first individual electrode 7D1.

In general, the ease of bending of the stacked material is affected by a member having a long distance from the neutral axis. As understood from FIG. 4, the second individual electrode 7D2 is farther from the neutral axis A1 than the first individual electrode 7D1. Therefore, the second thin film piezoelectric body 7P2 contributes more to the deformation of the entire piezoelectric element 7 than the first thin film piezoelectric body 7P1. On the other hand, from the viewpoint of the deformation of the piezoelectric element 7, the two individual electrodes 7D are members that make it difficult to deform the piezoelectric element 7. Therefore, in order to optimize the deformation of the entire piezoelectric element 7, it is preferable that the second individual electrode 7D2 corresponding to the second thin film piezoelectric body 7P2 having a larger contribution be made thinner than the first individual electrode 7D1 in priority, and the degree of hindrance of the deformation be reduced. In addition, an aspect in which both the first individual electrode 7D1 and the second individual electrode 7D2 are thinned is conceivable. However, in this aspect, when both the first individual electrode 7D1 and the second individual electrode 7D2 are thinned, electric resistance of the first individual electrode 7D1 and the second individual electrode 7D2 becomes too large, and the voltage drop from the coupling region XE1 to the coupling region XE2 is significantly generated. In view of this, the first individual electrode 7D1 corresponding to the first thin film piezoelectric body 7P1 having a relatively small contribution to the deformation of the entire piezoelectric element 7 is made relatively thick. Therefore, according to the first embodiment, the occurrence of the voltage drop of the two individual electrodes 7D can be suppressed while maintaining the ease of deformation of the piezoelectric element 7.

In addition, it is preferable that the insulating layer 7Z contains zirconium.

In addition, the liquid ejecting apparatus 100 includes the liquid ejecting head 1, and the control unit 91 that controls an ejection operation from the liquid ejecting head 1.

### 2. Second Embodiment

In a second embodiment, for a piezoelectric element 7a of the second embodiment, the two thin film piezoelectric bodies 7P and the insulating layer 7Z have shapes different from the two thin film piezoelectric bodies 7P and the insulating layer 7Z of the piezoelectric element 7 of the first embodiment, respectively, when viewed in the direction along the X axis. Hereinafter, the second embodiment will be described.

### 2-1. Piezoelectric Element 7a of Second Embodiment

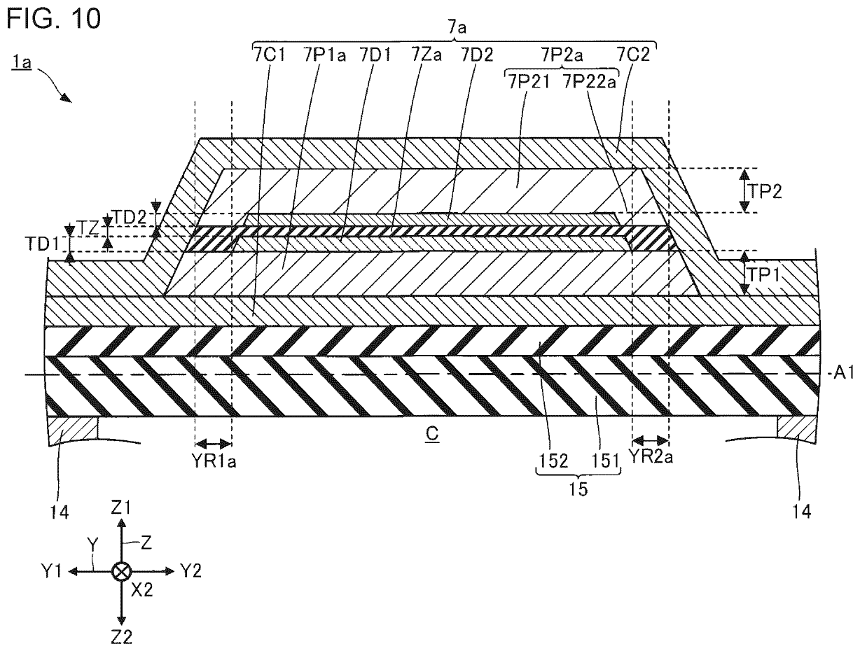

FIG. 10 is a sectional view of a part of a liquid ejecting head 1a according to the second embodiment. The sectional view illustrated in FIG. 10 shows a cross section taken along the line IV-IV in FIG. 2 when the liquid ejecting head 1 illustrated in FIG. 2 is replaced with the liquid ejecting head 1a. The liquid ejecting head 1a is different from the liquid ejecting head 1 in that the piezoelectric element 7a is provided instead of the piezoelectric element 7.

The piezoelectric element 7a is different from the piezoelectric element 7 in that the piezoelectric element 7a includes a first thin film piezoelectric body 7P1a instead of the first thin film piezoelectric body 7P1, includes an insulating layer 7Za instead of the insulating layer 7Z, and includes a second thin film piezoelectric body 7P2a instead of the second thin film piezoelectric body 7P2.

As illustrated in FIG. 10, in the second embodiment, in the direction along the Y axis, of the two regions in the piezoelectric element 7a in which the first individual electrode 7D1 and the second individual electrode 7D2 are not provided, a region positioned in the Y1 direction may be described as an inactive region YR1a, and a region positioned in the Y2 direction may be described as an inactive region YR2a. In the second embodiment, the inactive region YR1a and the inactive region YR2a are examples of a “third region”.

In the inactive region YR1a and the inactive region YR2a, the first common electrode 7C1, the first thin film piezoelectric body 7P1a, the insulating layer 7Za, the second thin film piezoelectric body 7P2a, and the second common electrode 7C2 are stacked in this order from the lower side to the upper side.

As illustrated in FIG. 10, the second thin film piezoelectric body 7P2a is different from the second thin film piezoelectric body 7P2 in that an inclined portion 7P22a is included instead of the inclined portion 7P22. An end of the inclined portion 7P22a in a Z2 direction is in contact with the insulating layer 7Za. As illustrated in FIG. 10, the second thin film piezoelectric body 7P2a is different from the second thin film piezoelectric body 7P2 in that the second thin film piezoelectric body 7P2a is formed to cover the second individual electrode 7D2 at the end portions in the Y1 direction and the Y2 direction in FIG. 4, and does not cover the first thin film piezoelectric body 7P1a, the first individual electrode 7D1, and the insulating layer 7Za. The insulating layer 7Za is different from the insulating layer 7Z in that the insulating layer 7Za is formed to cover the first individual electrode 7D1 at the end portions in the Y1 direction and the Y2 direction.

### 2-2. Manufacturing Method of Piezoelectric Element 7a

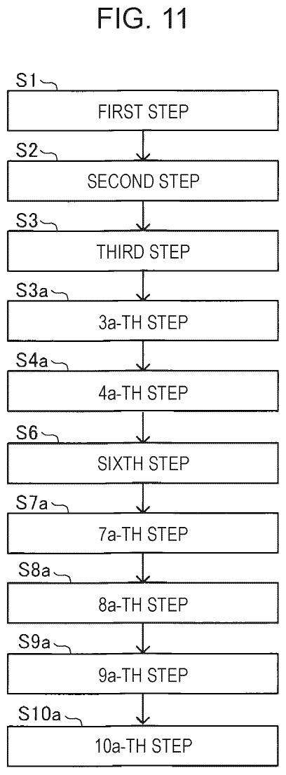

FIG. 11 is a flow illustrating a method of manufacturing the piezoelectric element 7a. As illustrated in FIG. 11, the manufacturing method of the piezoelectric element 7a includes a first step S1, a second step S2, a third step S3, a 3a-th step S3a, a 4a-th step S4a, a sixth step S6, a 7a-th step S7a, an 8a-th step S8a, a 9a-th step S9a, and a 10a-th step S10a. These steps are performed in this order. Among the steps illustrated in FIG. 11, the steps to which the same reference numerals as those in FIG. 9 are given are the same steps as the steps to which the same reference numerals as those in FIG. 9 are given, and thus the description thereof will be omitted.

In the 3a-th step S3a, the first individual electrode 7D1 is patterned. The patterning is performed by a known processing technique using etching or the like.

In the 4a-th step S4a, the insulating layer 7Za is formed to cover the first individual electrode 7D1.

In the 7a-th step S7a, the second individual electrode 7D2 is patterned.

In the 8a-th step S8a, the orientation control layer 7H is formed to cover the second individual electrode 7D2, and the second thin film piezoelectric body 7P2a is further formed.

In the 9a-th step S9a, the first thin film piezoelectric body 7P1a, the insulating layer 7Za, and the second thin film piezoelectric body 7P2a are patterned.

In the 10a-th step S10a, the second common electrode 7C2 is formed on the second thin film piezoelectric body 7P2a. The second common electrode 7C2 is formed by a known film forming technique and a known processing technique.

After the end of the 10a-th step S10a, the piezoelectric element 7a is manufactured by firing the piezoelectric element 7a at a high temperature.

After the end of the third step S3, that is, after the first individual electrode 7D1 is formed, the first individual electrode 7D1 may be patterned such that the end of the first individual electrode 7D1 in the Y1 direction and the end of the first individual electrode 7D1 in the Y2 direction are formed in the 3a-th step S3a, the 4a-th step S4a is performed, and then the first individual electrode 7D1 and the insulating layer 7Z may be patterned. According to this manufacturing method, the insulating layer 7Z can be prevented from being left in the inactive region XR1 and the inactive region XR2.

### 2-3. Summary of Second Embodiment

In the above, in the second embodiment, in the inactive region YR1a and the inactive region YR2a in which the first individual electrode 7D1 and the second individual electrode 7D2 are not provided in the direction along the Y axis, the first common electrode 7C1, the first thin film piezoelectric body 7P1a, the insulating layer 7Za, the second thin film piezoelectric body 7P2a, and the second common electrode 7C2 are stacked in this order from the lower side to the upper side.

Also in the second embodiment, in the same manner as in the first embodiment, the electric field generated by the first individual electrode 7D1 and the first common electrode 7C1 and the electric field generated by the second individual electrode 7D2 and the second common electrode 7C2 can be suppressed by the insulating layer 7Z.

The piezoelectric element 7a according to the second embodiment can improve the variability and reliability of the second thin film piezoelectric body 7P2a than the second thin film piezoelectric body 7P2, as compared with the piezoelectric element 7 according to the first embodiment. In the first place, there is a phenomenon that the film formation of the thin film piezoelectric body 7P on the inclined surface is more difficult than the film formation of the thin film piezoelectric body 7P on the horizontal surface. More specifically, there is a concern that the crystallinity of the thin film piezoelectric body 7P formed on the inclined surface is different from the crystallinity of the thin film piezoelectric body 7P formed on the horizontal surface, and thus there is a concern that the variability and reliability of the thin film piezoelectric body 7P formed on the inclined surface are lower than the variability and reliability of the thin film piezoelectric body 7P formed on the horizontal surface. As understood from FIGS. 4 and 10, a length of the inclined portion 7P22a in a direction in which the inclined portion 7P22a is inclined is shorter than a length of the inclined portion 7P22 in a direction in which the inclined portion 7P22 is inclined. Therefore, the second thin film piezoelectric body 7P2a can improve the variability and reliability as compared with the second thin film piezoelectric body 7P2. In addition, as understood from the comparison between FIG. 4 and FIG. 10, in the first embodiment, the first thin film piezoelectric body 7P1 and the second thin film piezoelectric body 7P2 have a contact point when viewed in the direction along the X axis.

When the first thin film piezoelectric body 7P1 and the second thin film piezoelectric body 7P2 come into contact with each other, there is a possibility that electrical noise is generated. When the electric noise is generated, there is a concern that the piezoelectric element 7 is deformed by a voltage of the noise, and the ink is ejected at a timing that is not intended by a manufacturer of the liquid ejecting head 1. Hereinafter, the manufacturer of the liquid ejecting head 1 may be referred to as a “head manufacturer”. On the other hand, in the second embodiment, when viewed in the direction along the X axis, the first thin film piezoelectric body 7P1a and the second thin film piezoelectric body 7P2a are divided by the insulating layer 7Za, and the first thin film piezoelectric body 7P1a and the second thin film piezoelectric body 7P2a do not come into contact with each other. Therefore, the piezoelectric element 7a can suppress the possibility of occurrence of the electrical noise as compared with the piezoelectric element 7.

On the other hand, the piezoelectric element 7 in the first embodiment is easier to manufacture than the piezoelectric element 7a in the second embodiment. Specifically, as understood from the description of FIG. 9, in the method of manufacturing the piezoelectric element 7, it is necessary to execute the patterning twice in the first step S1 to the ninth step S9. On the other hand, as understood from the description of FIG. 11, in the method of manufacturing the piezoelectric element 7a, it is necessary to execute the patterning three times from the first step S1 to the 9a-th step S9a. That is, in the method of manufacturing the piezoelectric element 7, the number of times of executing the patterning is small as compared with the method of manufacturing the piezoelectric element 7a, and thus, the piezoelectric element 7 is easily manufactured. In addition, in the piezoelectric element 7, since the insulating layer 7Z is not present in the inactive region YR1 and the inactive region YR2, a portion of the first common electrode 7C1 included in the inactive region YR1 and the inactive region YR2 is also electrically conducted. On the other hand, in the piezoelectric element 7a, the insulating layer 7Za is present in the inactive region YR1a and the inactive region YR2a. Therefore, the portion of the first common electrode 7C1 included in the inactive region YR1a and the inactive region YR2a is less likely to have a current flow as compared with the first embodiment. Therefore, the portion of the first common electrode 7C1 included in the inactive region YR1 and the inactive region YR2 can improve the conductivity as compared with the second embodiment.

### 3. Modification Example

The embodiments exemplified above can be modified in various ways. Specific modification aspects that can be applied to each of the above-described embodiments will be described below. Any two or more aspects arbitrarily selected from the following examples can be combined as appropriate as long as there is no contradiction.

### 3-1. First Modification Example

In each of the above-described aspects, the second individual electrode 7D2 is described as being thinner than the first individual electrode 7D1, but the present disclosure is not limited thereto. For example, the second individual electrode 7D2 may be thicker than the first individual electrode 7D1. Hereinafter, the first modification example will be described.

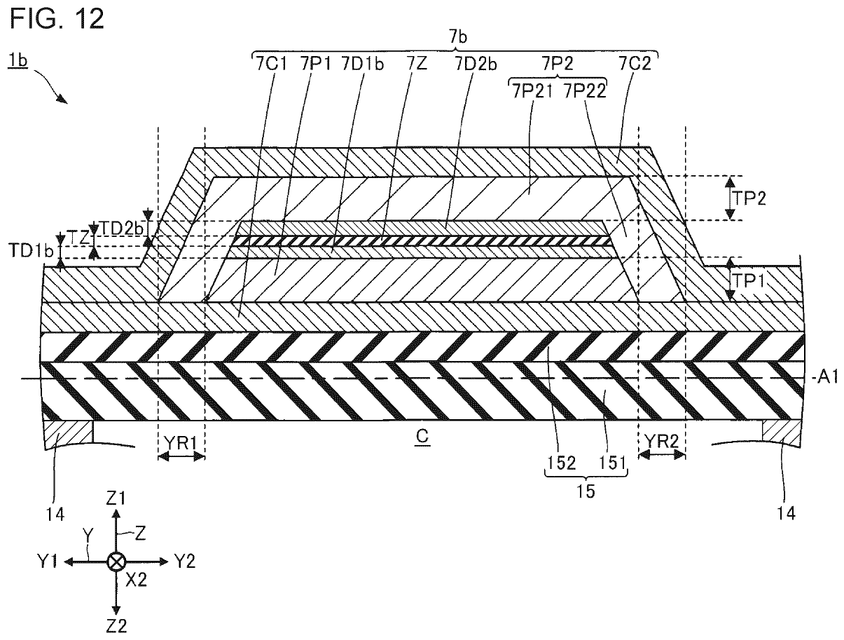

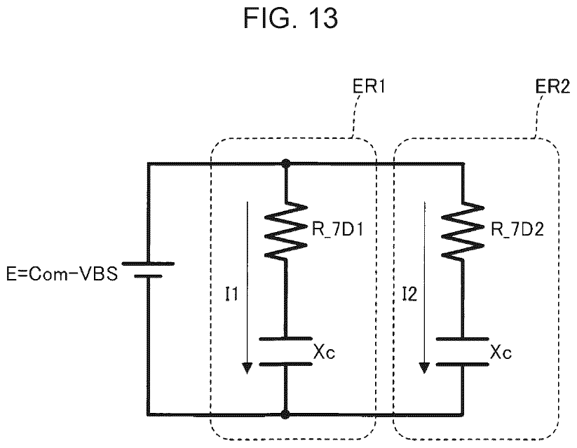

FIG. 12 is a sectional view of a part of a liquid ejecting head 1b according to the first modification example. The sectional view illustrated in FIG. 12 shows a cross section taken along the line IV-IV in FIG. 2 when the liquid ejecting head 1 illustrated in FIG. 2 is replaced with the liquid ejecting head 1b. The liquid ejecting head 1b is different from the liquid ejecting head 1 in that a piezoelectric element 7b is provided instead of the piezoelectric element 7.

The piezoelectric element 7b is different from the piezoelectric element 7 in that the piezoelectric element 7b includes a first individual electrode 7D1b instead of the first individual electrode 7D1 and includes a second individual electrode 7D2b instead of the second individual electrode 7D2.

A thickness TD2b of the second individual electrode 7D2b in the direction along the Z axis is longer than a thickness TD1b of the first individual electrode 7D1b in the direction along the Z axis. When the thickness TZ of the insulating layer 7Z in the direction along the Z axis is also included, in the first modification example, a relationship of Expression (2) is obtained.

$$TZ < TD 1 b < TD 2 b \qquad ( 2 )$$

As described above, according to the first modification example, the second individual electrode 7D2b is thicker than the first individual electrode 7D1b.

The piezoelectric element 7a of the present disclosure can be replaced with an equivalent circuit as illustrated in FIG. 13 when considering the electric system. That is, a first route ER1 that passes through the first individual electrode 7D1b, the first thin film piezoelectric body 7P1, and the first common electrode 7C1 and is coupled to the voltage application circuit 910, and a second route ER2 that passes through the second individual electrode 7D2b, the second thin film piezoelectric body 7P2, and the second common electrode 7C2 and is coupled to the voltage application circuit 910 are coupled in parallel. At this time, a current flowing through the first route ER1 is I1, a current flowing through the second route ER2 is 12, an electric resistance of the first individual electrode 7D1b is R_7D1, an electric resistance of the second individual electrode 7D2b is R_7D2, and a voltage applied from the voltage application circuit 910 to each of the first route ER1 and the second route ER2 is E (equal to the pressure difference between the driving voltage Com and the reference voltage VBS). Here, when the materials, thicknesses, and the like of the first thin film piezoelectric body 7P1 and the second thin film piezoelectric body 7P2 are substantially the same, a capacitive reactance Xc can also be approximated to the same value. In addition, since the first common electrode 7C1 and the second common electrode 7C2 have different shapes as illustrated in FIG. 12, the electric resistance is naturally different. However, since these are originally formed to be long in the XY plane, the electric resistance is small, and the difference can be ignored. From these premises, a difference between the first route ER1 and the second route ER2 is only the electric resistance R_7D1 of the first individual electrode 7D1b and the electric resistance R_7D2 of the second individual electrode 7D2b. Here, when the second individual electrode 7D2b is thicker than the first individual electrode 7D1b, the electric resistance R_7D2 is smaller than the electric resistance R_7D1. Therefore, it can be seen that the current I2 flowing through the second route ER2 is larger than the current I1 flowing through the first route ER1. Since the magnitude relation of the current and the capacitive reactance Xc of the first thin film piezoelectric body 7P1 and the second thin film piezoelectric body 7P2 are the same, it can be seen that the voltage actually applied to the second thin film piezoelectric body 7P2 is greater than that of the first thin film piezoelectric body 7P1. As described above, the second thin film piezoelectric body 7P2 far from the neutral axis A1 contributes more to the deformation of the entire piezoelectric element 7 than the first thin film piezoelectric body 7P1. Therefore, in the piezoelectric element 7a of the present disclosure, a greater voltage can be applied to the second thin film piezoelectric body 7P2 which has a larger contribution to the deformation of the entire piezoelectric element 7. Therefore, the ejection characteristics can be suitably optimized.

As described above, the piezoelectric element 7 illustrated in FIG. 4 is preferable when considering a physical aspect, and the piezoelectric element 7b illustrated in FIG. 12 is preferable when considering an electrical aspect. This is not something that can be said to be better in general, and a suitable configuration varies depending on which of the rigidity and elasticity (how easily the piezoelectric body is deformed) and the electric resistance of each individual electrode is more advantageous.

### 3-2. Second Modification Example

In each of the above-described aspects, the first individual electrode 7D1 and the second individual electrode 7D2 are coupled to each other at both of one end and another end of the first individual electrode 7D1 and the second individual electrode 7D2 in the direction along the X axis, but may be coupled to only one end thereof. It is preferable that only one end is the coupling region XE1. Specifically, in the aspect in which only the coupling region XE1 is coupled, the voltage drop occurs in the length of the active region AAR in the direction along the X axis at an end portion of the first individual electrode 7D1 in the X2 direction and an end portion of the second individual electrode 7D2 in the X2 direction. On the other hand, in the aspect in which only the coupling region XE2 is coupled, a current supplied to the end portion of the first individual electrode 7D1 in the X1 direction passes through the end portion of the second individual electrode 7D2 in the X1 direction to the end portion in the X2 direction, the coupling region XE2, and the end portion of the first individual electrode 7D1 in the X2 direction to the end portion in the X1 direction. Therefore, in the aspect in which only the coupling region XE2 is coupled, the voltage drop corresponding to twice the length of the active region AAR in the direction along the X axis occurs at the end portion of the first individual electrode 7D1 in the X1 direction. Therefore, in the aspect in which only the coupling region XE1 is coupled, it is possible to suppress the voltage drop as compared with the aspect in which only the coupling region XE2 is coupled.

### 3-3. Third Modification Example

In each of the above-described aspects, at least one end of both ends of one end and another end of the first individual electrode 7D1 and the second individual electrode 7D2 in the direction along the X axis are coupled to each other but may not be coupled to each other. The individual wiring portion 73 may separately have a wiring for applying the driving voltage Com to the first individual electrode 7D1 and a wiring for applying the driving voltage Com to the second individual electrode 7D2. According to the third modification example, the driving voltage Com to be applied to the first individual electrode 7D1 and the driving voltage Com to be applied to the second individual electrode 7D2 can be made different from each other.

### 3-4. Fourth Modification Example

In each of the above-described aspects, the insulating layer 7Z is thinner than the first individual electrode 7D1 and the second individual electrode 7D2, but the present disclosure is not limited thereto. The insulating layer 7Z may be thicker than at least one electrode of the first individual electrode 7D1 and the second individual electrode 7D2. For example, the insulating layer 7Z may be thicker than the first individual electrode 7D1, and the second individual electrode 7D2 may be thicker than the insulating layer 7Z. That is, the insulating layer 7Z, the first individual electrode 7D1, and the second individual electrode 7D2 may be thickened as they are separated from the neutral axis A1.

### 3-5. Fifth Modification Example

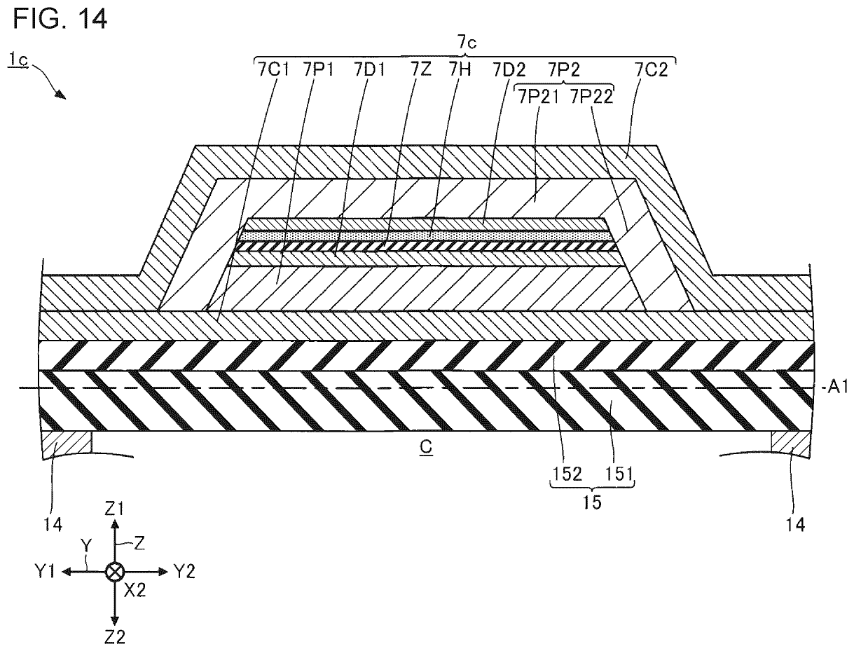

In each of the above-described aspects, the orientation control layer 7H is provided between the first thin film piezoelectric body 7P1 and the first common electrode 7C1, and between the second thin film piezoelectric body 7P2 and the second common electrode 7C2, but the present disclosure is not limited thereto. FIG. 14 is a sectional view of a part of a liquid ejecting head 1c according to a fifth modification example. The sectional view illustrated in FIG. 14 shows a cross section taken along the line IV-IV in FIG. 2 when the liquid ejecting head 1 illustrated in FIG. 2 is replaced with the liquid ejecting head 1c. The liquid ejecting head 1c is different from the liquid ejecting head 1 in that a piezoelectric element 7c is provided instead of the piezoelectric element 7.

The piezoelectric element 7c is different from the piezoelectric element 7 in that the orientation control layer 7H is provided between the insulating layer 7Z and the second individual electrode 7D2. By providing the orientation control layer 7H at this position, the orientation control layer 7H preferentially orients the crystal of the second thin film piezoelectric body 7P2 to the (100) plane, and thus the piezoelectric characteristics of the piezoelectric element 7 can be improved as compared with a case where the crystal is preferentially oriented to the (110) plane. In particular, when a single crystal of Ti is used as the orientation control layer 7H, the orientation control may not be suitably performed unless the single crystal is directly stacked on the ZrO₂ which is the insulating layer. Therefore, when a single crystal of Ti is used for the orientation control layer 7H, the orientation of the second thin film piezoelectric body 7P2 can be particularly suitably controlled according to the present configuration.

### 3-6. Sixth Modification Example

In each of the above-described aspects, a serial type liquid ejecting apparatus in which the transport body 931 on which the liquid ejecting head 1 is mounted is reciprocated is exemplified, but the present disclosure can also be applied to a line type liquid ejecting apparatus in which the plurality of nozzles N are distributed over the entire width of the medium M.

### 3-7. Other Modification Examples

The above-described liquid ejecting apparatus can be employed in various devices such as a facsimile machine and a copier, in addition to a device dedicated to printing. However, the application of the liquid ejecting apparatus of the present disclosure is not limited to printing. For example, a liquid ejecting apparatus that ejects a solution of a coloring material is used as a manufacturing device that forms a color filter of a liquid crystal display device. In addition, the liquid ejecting apparatus that ejects a solution of a conductive material is used as a manufacturing device that forms wirings and electrodes of a wiring substrate.

What is claimed is:

1. A liquid ejecting head, comprising, stacked in this order from a lower side to an upper side along a stacking direction intersecting an arrangement direction and an extending direction intersecting the arrangement direction:
a pressure chamber substrate in which a plurality of pressure chambers are provided to be arranged in the arrangement direction;
a diaphragm;
a first common electrode which is commonly provided for the plurality of pressure chambers and to which a reference voltage that does not change over time is applied;
a first thin film piezoelectric body;
a first individual electrode which is individually provided for the plurality of pressure chambers so as to extend in the extending direction and to which a driving voltage that changes over time is applied;
an insulating layer;
a second individual electrode which is individually provided for the plurality of pressure chambers so as to extend in the extending direction and to which the driving voltage that changes over time is applied;
a second thin film piezoelectric body; and
a second common electrode which is commonly provided for the plurality of pressure chambers and to which the reference voltage is applied,
wherein the first individual electrode and the second individual electrode are blocked by the insulating layer in a first region where the first individual electrode and the second individual electrode overlap the pressure chamber when viewed in the stacking direction.

2. The liquid ejecting head according to claim 1, wherein the first individual electrode and the second individual electrode are coupled to each other in a second region in which the first individual electrode and the second individual electrode do not overlap the pressure chamber when viewed in the stacking direction.

3. The liquid ejecting head according to claim 2, wherein the first individual electrode and the second individual electrode are coupled to each other in both of one end and another end of the first individual electrode and the second individual electrode in the extending direction in the second region.

4. The liquid ejecting head according to claim 2, wherein, in a third region in which the first individual electrode and the second individual electrode are not provided in the arrangement direction, the first common electrode, the first thin film piezoelectric body, the insulating layer, the second thin film piezoelectric body, and the second common electrode are stacked in this order from the lower side to the upper side.

5. The liquid ejecting head according to claim 2, wherein, in a third region in which the first individual electrode and the second individual electrode are not provided in the arrangement direction, the first common electrode, the second thin film piezoelectric body, and the second common electrode are stacked in this order from the lower side to the upper side, and the first thin film piezoelectric body and the insulating layer are not stacked.

6. The liquid ejecting head according to claim 1, wherein the insulating layer is thinner than the first individual electrode and the second individual electrode.

7. The liquid ejecting head according to claim 1, wherein the second individual electrode is thinner than the first individual electrode.

8. The liquid ejecting head according to claim 1, wherein the second individual electrode is thicker than the first individual electrode.

9. The liquid ejecting head according to claim 1, wherein the insulating layer contains zirconium.

10. The liquid ejecting head according to claim 1, wherein, in the first region, an orientation control layer containing titanium for controlling orientation of the second thin film piezoelectric body is provided between the insulating layer and the second individual electrode.

11. A liquid ejecting apparatus comprising:
the liquid ejecting head according to claim 1; and
a control unit that controls an ejection operation of the liquid ejecting head.
